(19) United States
(12) Patent Application Publication
(10) Pub. No.: US 2022/0148504 A1
(43) Pub. Date: May 12, 2022

(54) Display Panel, Driving Method thereof, and Display Apparatus

(71) Applicant: BOE Technology Group Co., Ltd., Beijing (CN)

(72) Inventors: Hongrun WANG, Beijing (CN); Hui ZHANG, Beijing (CN); Changfeng LI, Beijing (CN); Fuqiang LI, Beijing (CN); Xue DONG, Beijing (CN)

(21) Appl. No.: 17/485,521

(22) Filed: Sep. 27, 2021

(30) Foreign Application Priority Data
Nov. 12, 2020 (CN) 202011265261.8

(51) Int. Cl. G09G 3/3233; G06F 3/01; G09G 3/20

(52) U.S. Cl. CPC G09G 3/3233; G06F 3/013; G09G 3/2074; G09G 2310/08; G09G 2320/068; G09G 2300/0452; G09G 2340/0407; G09G 2300/0842; G09G 2320/0686; G09G 2300/0443

(57) ABSTRACT

A display panel, a method for driving the display panel, and a display apparatus are provided. The display panel includes multiple pixel islands. At least one pixel island includes multiple sub-pixels, at least one of the sub-pixel includes a pixel driving circuit and a light-emitting device, and at least one pixel driving circuit is connected to the light-emitting devices in the multiple sub-pixels. The multiple sub-pixels are located in one pixel island or in different pixel islands, and the at least one pixel driving circuit is connected to a time-sharing control signal line, wherein the time-sharing control signal line is used to control multiple light-emitting devices to emit light at the same time or to emit light in a time-sharing manner.

### CROSS-REFERENCE TO RELATED APPLICATION

The present application claims priority of Chinese Patent Application No. 202011265261.8 filed to the CNIPA on Nov. 12, 2020, the content of which is hereby incorporated by reference.

### TECHNICAL FIELD

The present disclosure relates to, but is not limited to, the field of display technology, and in particular to a display panel, a method for driving the display panel, and a display apparatus.

### BACKGROUND

An organic light-emitting Diode (OLED) is an active light-emitting display apparatus, which has advantages such as self-illumination, ultra-thinness, fast response speed, wide viewing angle and low power consumption. With the continuous development of OLED display technology, high PPI (Pixels Per Inch) display has gradually attract more attention.

### SUMMARY

The following is a summary of subject matters detailed herein. The summary is not intended to limit the scope of protection of the claims.

In an aspect, an embodiment of the present disclosure provides display panel, which includes multiple pixel islands. At least one pixel island includes multiple sub-pixels, at least one sub-pixel includes a pixel driving circuit and a light-emitting device, and at least one pixel driving circuit of the pixel driving circuits is connected to the light-emitting devices in the multiple sub-pixels. The multiple sub-pixels are located in one pixel island or in different pixel islands, and the at least one pixel driving circuit is connected to a time-sharing control signal line, wherein the time-sharing control signal line is configured to control multiple light-emitting devices to emit light at the same time or to emit light in a time-sharing manner.

In another aspect, an embodiment of the present disclosure further provides a method for driving a display panel, which is any of the foregoing display panels, and the driving method includes:

acquiring a gaze position of a viewer on the display panel, and determining pixel islands of a gaze zone and pixel islands of a non-gaze zone in the display panel according to the gaze position; and

controlling a resolution of the pixel islands in the gaze zone to be greater than a resolution of the pixel islands in the non-gaze zone by the time-sharing control signal line.

In another aspect, an embodiment of the present disclosure further provides a display apparatus which includes any one of the foregoing display panels.

Of course, the implementation of any product or method of the present disclosure does not necessarily need to realize all the advantages mentioned above at the same time. Other features and advantages of the present disclosure will be set forth in the following embodiments of the description, and in part will become apparent from the embodiments of the description, or be learned by practice of the present disclosure. The purpose and other advantages of the embodiments of the present disclosure may be realized and obtained through the structure specifically pointed out in the description, the claims and the drawings.

Other aspects can be understood upon reading and understanding of the drawings and the detailed description.

### BRIEF DESCRIPTION OF DRAWINGS

The drawings are used to provide a further understanding of technical solutions of the present disclosure and constitute a part of the description, which are used together with the embodiments of the present disclosure to explain the technical solutions of the present disclosure and do not constitute limitations on the technical solutions of the present disclosure. The shape and size of each component in the drawings do not reflect true scales and only to be used to schematically illustrate contents of the present disclosure.

FIG. 1 is a schematic diagram of a circuit structure of an OLED display apparatus.

FIG. 2a is a schematic plan view of a structure of a display region of a display substrate according to an embodiment of the present disclosure.

FIG. 2b is another schematic plan view of a structure of a display region of a display substrate according to an embodiment of the present disclosure.

FIG. 3 is an equivalent circuit diagram of a pixel driving circuit.

FIG. 4 is an equivalent circuit diagram of a pixel driving circuit according to an embodiment of the present disclosure.

FIG. 5 is a diagram showing a connection relation between a pixel driving circuit and a pixel island according to an embodiment of the present disclosure.

FIG. 6 is a schematic diagram showing display characteristics of a 3D display data column.

FIG. 7 is an equivalent circuit diagram of a pixel driving circuit according to an embodiment of the present disclosure.

FIG. 8 is a timing diagram of a light-emitting control signal according to an embodiment of the present disclosure.

FIG. 9 is a schematic flowchart of a driving method of a display panel according to an embodiment of the present disclosure.

FIG. 10 is a schematic view of a gaze zone according to an embodiment of the present disclosure.

FIG. 11 is a diagram showing a connection relation between a pixel driving circuit and a pixel island according to another embodiment of the present disclosure.

FIG. 12 is an equivalent circuit diagram of a pixel driving circuit according to another embodiment of the present disclosure.

FIG. 13a is a timing diagram of a light-emitting control signal according to another embodiment of the present disclosure.

FIG. 13b is a timing diagram of another light-emitting control signal according to another embodiment of the present disclosure.

FIG. 14 is a schematic flowchart of a driving method of a display panel according to another embodiment of the present disclosure.

### DETAILED DESCRIPTION

The present disclosure describes multiple embodiments, but the description is exemplary rather than restrictive. It will be apparent to those of ordinary skills in the art that there may be more embodiments and implementation solutions within the scope of the embodiments described in the present disclosure. Although a number of possible combinations of features are shown in the drawings and discussed in the embodiments, many other combinations of the disclosed features are also possible. Unless expressly limited otherwise, any feature or element of any embodiment may be used in combination with, or in place of, any other feature or element of any other embodiment.

The present disclosure includes and contemplates combinations of features and elements known to those of ordinary skills in the art. The embodiments, features, and elements disclosed in the present disclosure may also be combined with any conventional feature or element to form a unique scheme defined by the claims. Any feature or element of any embodiment may also be combined with a feature or an element from another scheme to form another unique scheme defined by the claims. Therefore, it should be understood that any feature shown or discussed in the present disclosure may be implemented independently or in any appropriate combination. Therefore, the embodiments are not limited except as by the appended claims and their equivalents. In addition, one or more modifications and alterations may be made within the protection scope of the appended claims.

In addition, when a representative embodiment is described, a method or a process may already be presented as a specific sequence of steps in the specification. However, to the extent that the method or process does not depend on a particular order of steps described herein, the method or process should not be limited to the particular order of steps described. As will be appreciated by those of ordinary skills in the art, other orders of steps are also possible. Therefore, the particular order of steps set forth in the specification should not be construed as limitations on the claims. Moreover, execution of the steps of the method of the process in the claims for the method or the process should not be limited to the order described, and it can be easily understood by those skilled in the art that these orders may be changed and they still fall within the spirit and scope of the embodiments of the present disclosure.

In the drawings, a size of a constituent element, or a thickness of a layer or an area, is sometimes exaggerated for clarity. Therefore, an implementation of the present disclosure is not necessarily limited to the size shown, and a shape and size of each component in the drawings do not reflect true scales. In addition, the drawings schematically illustrate ideal examples, and any embodiment of the present disclosure is not limited to the shapes, numerical values or the like illustrated in the drawings.

Unless otherwise defined, technical terms or scientific terms used in the present disclosure have the same meanings as commonly understood by those of ordinary skill in the art to which the present disclosure pertains. “First”, “second”, and similar terms used in the present disclosure do not represent any sequence, number, or significance but are only used to distinguish different components. In the present disclosure, “multiple” may mean two or more than two. The wording “include” or “include”, etc. means that an element or article that precedes the word is inclusive of the element or article listed after the word and equivalents thereof, but does not exclude other elements or articles. Similar wordings such as “couple”, “connect” or “link” are not limited to physical or mechanical connections, but may include electrical connections, whether direct or indirect. “Electrical connection” includes a case where constituent elements are connected together through an element with a certain electrical action. The “element having a certain electrical action” is not particularly limited as long as it can send and receive an electrical signal between the connected constituent components. Examples of “the element having a certain electrical action” not only include electrodes and wirings, but also include switching elements such as transistors, resistors, inductors, capacitors, and other elements with one or more functions.

In the present disclosure, for the sake of convenience, wordings such as “central”, “upper”, “lower”, “front”, “rear”, “vertical”, “horizontal”, “top”, “bottom”, “inner”, “outer” and the others describing the orientation or positional relations are used to depict positional relations between elements with reference to the drawings, which are only for facilitating describing the present disclosure and simplifying the description, rather than indicating or implying that the device or element referred to must have a specific orientation, or must be constructed and operated in a particular orientation, and therefore, these wordings cannot be construed as limitations on the present disclosure. The positional relations between the constituent elements may be appropriately changed according to the direction in which each constituent element is described. Therefore, the wordings described herein are not restrictive, and may be appropriately replaced according to the situation.

In the present disclosure, a transistor refers to an element including at least three terminals, namely, a gate electrode, a drain electrode and a source electrode. The transistor has a channel region between the drain electrode (drain electrode terminal, drain region, or drain electrode) and the source electrode (source electrode terminal, source region, or source electrode), and a current can flow through the drain electrode, the channel region, and the source electrode. In the present disclosure, the channel region refers to a region through which the current mainly flows.

In the present disclosure, it may be the case that a first electrode is a drain electrode and a second electrode is a source electrode, and it may also be the case that the first electrode is a source electrode and the second electrode is a drain electrode. In a case of using transistors with opposite polarities or in a case where the direction of the current in circuit operation changes, functions of the “source electrode” and the “drain electrode” may be interchanged sometimes. Therefore, in the present disclosure, “the source electrode” and “the drain electrode” are interchangeable.

In the present disclosure, “parallel” refers to a state in which an angle formed by two straight lines is above −10 degrees and below 10 degrees, and thus may include a state in which the angle is above −5 degrees and below 5 degrees. In addition, “perpendicular” refers to a state in which an angle formed by two straight lines is above 80 degrees and below 100 degrees, and thus may include a state in which the angle is above 85 degrees and below 95 degrees.

In the present disclosure, “film” and “layer” are interchangeable. For example, “conductive layer” may be replaced with “conductive film” sometimes. Similarly, “insulating film” may be replaced with “insulating layer” sometimes.

In this specification, “about” refers to a numerical value within the range of allowable process and measurement errors without strictly limiting the limit.

For keeping the following description of the embodiments of the present disclosure clear and concise, detailed descriptions about part of known functions and known components are omitted in the present disclosure. The drawings of the embodiments of the present disclosure only involve the structures involved in the embodiments of the present disclosure, and the other structures may refer to conventional designs.

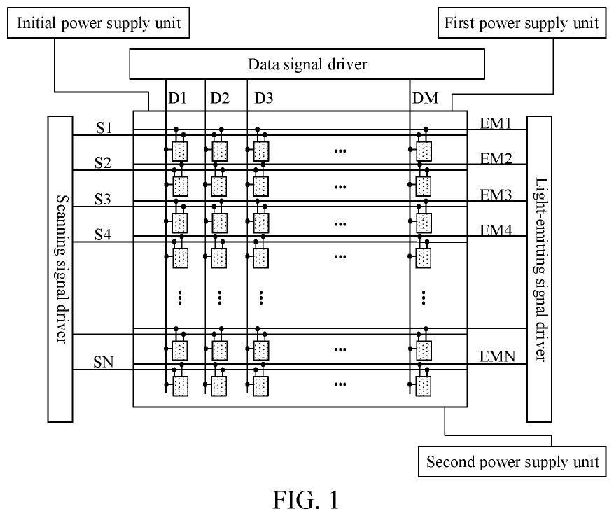

FIG. 1 is a schematic diagram of a circuit structure of an OLED display apparatus. As shown in FIG. 1, the OLED display apparatus may include a scanning signal driver, a data signal driver, a light-emitting signal driver, an OLED display panel, a first power supply unit, a second power supply unit and an initial power supply unit. In an exemplary embodiment, the OLED display substrate at least includes multiple scanning signal lines (S1 to SN), multiple data signal lines (D1 to DM) and multiple light-emitting signal lines (EM1 to EMN). The scanning signal driver is configured to sequentially supply scanning signals to the multiple scanning signal lines (S1 to SN), the data signal driver is configured to supply data signals to the multiple data signal lines (D1 to DM), and the light-emitting signal driver is configured to sequentially supply light-emitting control signals to the multiple light-emitting signal lines (EM1 to EMN). In an exemplary implementation mode, the multiple scanning signal lines and the multiple light-emitting signal lines extend in a horizontal direction, and the multiple data signal lines extend in a vertical direction. The display apparatus includes multiple sub-pixels, wherein at least one sub-pixel includes a pixel driving circuit and a light-emitting device. The pixel driving circuit is connected to a scanning signal line, a light-emitting control line, and a data signal line respectively, and the pixel driving circuit is configured to receive a data voltage transmitted by the data signal line and output a corresponding current to the light-emitting device under the control of the scanning signal line and the light-emitting signal line. The light-emitting device is configured to emit light of corresponding brightness in response to the current output by the pixel driving circuit of the sub-pixel where it is located. The first power supply unit is configured to provide a first power supply voltage to the pixel driving circuit through a first power supply line, the second power supply unit is configured to provide a second power supply voltage to the pixel driving circuit through a second power supply line, and the initial power supply unit is configured to provide an initial power supply voltage to the pixel driving circuit through an initial signal line.

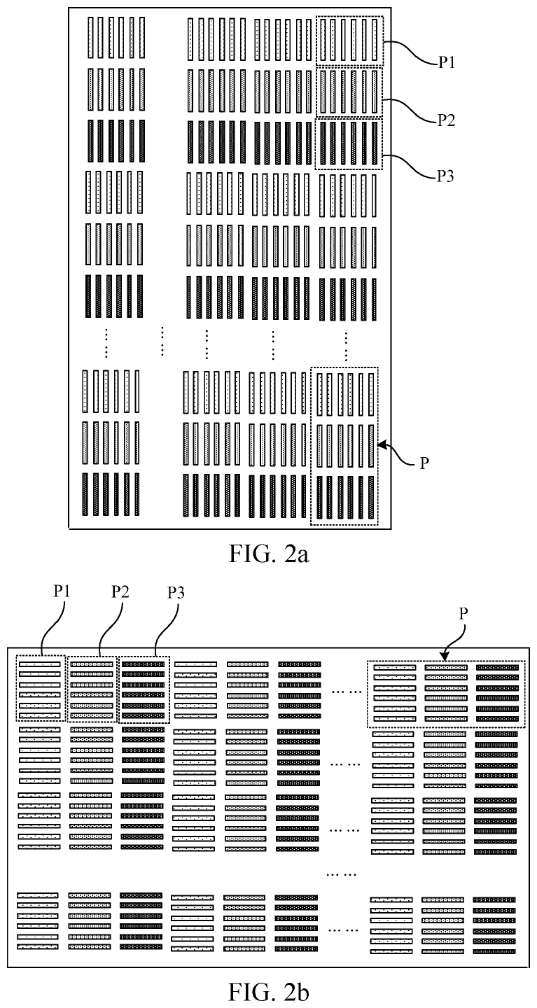

FIG. 2 is a schematic plan view of a structure of a display region of a display substrate according to an embodiment of the present disclosure. As shown in FIG. 2, the display region may include multiple groups of pixel islands P arranged in a matrix. Any group of pixel islands P includes a first pixel island P1 that emits light of a first color, a second pixel island P2 that emits light of a second color, and a third pixel island P3 that emits light of a third color. The first pixel island P1, the second pixel island P2 and the third pixel island P3 adjacent to each other form a repetitive unit. Sub-pixels in the same pixel island display the same color. The figure only illustrates one pixel island containing 6 sub-pixels as an example, which is not limited by the present disclosure. In an exemplary embodiment, a group of pixel islands P may include red (R) pixel islands, green (G) pixel islands, and blue (B) pixel islands, or may include red pixel islands, green pixel islands, blue pixel islands, and white (W) pixel islands, which are not limited in the present disclosure. In an exemplary embodiment, the shape of sub-pixels in a pixel island may be rectangular. FIG. 2a is an example of pixel arrangement. In FIG. 2a, in the horizontal direction, one row of pixel islands displays the same color. For example, the first row of pixel islands displays the first color, the second row of pixel islands displays the second color, and the third row of pixel islands displays the third color. FIG. 2b is an example of another pixel arrangement. In FIG. 2b, one column of pixel islands displays the same color. For example, the first column of pixel islands displays the first color, the second column of pixel islands displays the second color, and the third column of pixel islands displays the third color.

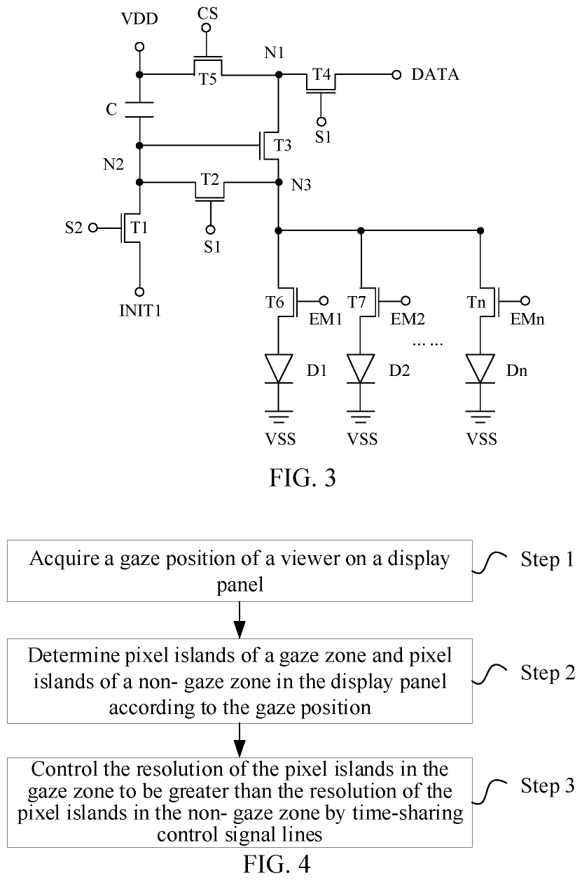

In an exemplary implementation, the pixel driving circuit may have a structure of 3T1C, 4T1C, 5T1C, 5T2C, 6T1C or 7T1C. FIG. 3 is an equivalent circuit diagram of a pixel driving circuit according to an embodiment of the present disclosure. The pixel driving circuit shown in FIG. 3 is a variant of the 6T1C structure, which may include 6 switching transistors (first transistor T1 to sixth transistor T6), a storage capacitor C and multiple signal lines (a data signal line DATA, a time-sharing control signal line CS, a first scanning signal line S1, a second scanning signal line S2, a first initial signal line INIT1, a first power supply line VSS, a second power supply line VDD, and a light-emitting signal line EM). Among them, the first initial signal line INIT1 and the second initial signal line INIT2 may be the same signal line.

In an exemplary implementation mode, a control electrode of the first transistor T1 is connected to the second scanning signal line S2, a first electrode of the first transistor T1 is connected to the first initial signal line INIT1, and a second electrode of the first transistor is connected to a second node N2. A control electrode of the second transistor T2 is connected to the first scanning signal line S1, a first electrode of the second transistor T2 is connected to the second node N2, and a second electrode of the second transistor T2 is connected to a third node N3. A control electrode of a third transistor T3 is connected to the second node N2, a first electrode of the third transistor T3 is connected to a first node N1, and a second electrode of the third transistor T3 is connected to the third node N3. A control electrode of the fourth transistor T4 is connected to the first scanning signal line S1, a first electrode of the fourth transistor T4 is connected to the data signal line DATA, and a second electrode of the fourth transistor T4 is connected to the first node N1. A control electrode of the fifth transistor T5 is connected to the time-sharing control signal line CS, a first electrode of the fifth transistor T5 is connected to the second power supply line VDD, and a second electrode of the fifth transistor T5 is connected to the first node N1. A control electrode of the sixth transistor T6 is connected to the first light-emitting signal line EM1, a first electrode of the sixth transistor T6 is connected to the third node N3, and a second electrode of the sixth transistor T6 is connected to a first electrode of a first light-emitting device. The second electrode of the first light-emitting device is connected to the first power supply line VSS. A control electrode of the seventh transistor T7 is connected to the second light-emitting signal line EM2, a first electrode of the seventh transistor T7 is connected to the third node N3, and a second electrode of the seventh transistor T7 is connected to a first electrode of a second light-emitting device. The second electrode of the second light-emitting device is connected to the first power supply line VSS. A control electrode of the n-th transistor Tn is connected to the n-th light-emitting signal line EMn, a first electrode of the n-th transistor Tn is connected to the third node N3, and a second electrode of the n-th transistor Tn is connected to a first electrode of the n-th light-emitting device. A second electrode of the n-th light-emitting device is connected to the first power supply line VSS. A first terminal of the storage capacitor C is connected to the second power supply line VDD, and a second terminal of the storage capacitor C is connected to the second node N2.

In an exemplary implementation, the first transistor T1 to the n-th transistor Tn may be P-type transistors or N-type transistors. Use of the same type of transistors in the pixel driving circuit can simplify the process flow, reduce the process difficulties of a display panel, and improve the yield of the product. In some possible implementation modes, the first transistor T1 to the n-th transistor Tn may include P-type transistors and N-type transistors.

In an exemplary implementation, the second electrodes of the n light-emitting devices are all connected to the first power supply line VSS. A signal of the first power supply line VSS is a low level signal and a signal of the second power supply line VDD is a high level signal that is continuously supplied. The first scanning signal line S1 is a scanning signal line in a pixel driving circuit of the current display row, and the second scanning signal line S2 is a scanning signal line in a pixel driving circuit of a previous display row. That is, for an n-th display row, the first scanning signal line S1 is S(n), the second scanning signal line S2 is S(n−1), and the second scanning signal line S2 of the current display row and the first scanning signal line S1 in the pixel driving circuit of the previous display row are the same signal line, thus signal lines of the display panel can be reduced and a narrow bezel of the display panel can be achieved.

Embodiments of the present disclosure provide display panel, which includes multiple pixel islands. At least one pixel island includes multiple sub-pixels, at least one sub-pixel includes a pixel driving circuit and a light-emitting device, and at least one pixel driving circuit is connected to the light-emitting devices in the multiple sub-pixels. The multiple sub-pixels are located in one pixel island or in different pixel islands, and the at least one pixel driving circuit is connected to a time-sharing control signal line, wherein the time-sharing control signal line is used to control multiple light-emitting devices to emit light at the same time or to emit light in a time-sharing manner. By controlling of the multiple light-emitting devices to emit light at the same time or in a time-sharing manner, local resolution may be reduced so that display resources can be saved.

In an exemplary embodiment, sub-pixels in the same pixel island display the same color.

In an exemplary embodiment, the at least one pixel driving circuit is connected to the light-emitting devices in the multiple sub-pixels, which includes one of the following cases:

In case 1, one pixel driving circuit is connected to all sub-pixels in one pixel island, that is, one pixel driving circuit is used to drive one pixel island. This solution may increase the display resolution while making fewer changes to the circuit.

In case 2, one pixel driving circuit is connected to the x-th sub-pixel in a first pixel island and the x-th sub-pixel in a second pixel island, wherein the first pixel island and the second pixel island are adjacent pixel islands. At this time, multiple pixel driving circuits may be required to jointly drive multiple pixel islands, or in other words, one pixel island may be jointly driven by multiple pixel driving circuits. The complexity of the control chip and the number of signal lines can be reduced by the solution of joint driving.

In an exemplary embodiment, the multiple pixel islands include pixel islands of a first color, pixel islands of a second color and pixel islands of a third color, and three adjacent pixel islands, i.e., a pixel island of the first color, a pixel island of the second color and a pixel island of the third color form a pixel island group, and the pixel island groups are disposed in an array in the display panel. The fact that the three pixel islands are adjacent means that the pixel islands of the three colors are disposed in sequence and a relation of color sequence is not limited in the present disclosure. The arrangement sequence may be along the display row direction or along the display column direction.

In an exemplary embodiment, the sub-pixels in the pixel islands may be rectangular, and multiple rectangular sub-pixels in one pixel island are disposed in a manner that the long sides of the rectangles are adjacent, and extension lines of the long sides are parallel to the display rows (as shown in FIG. 2b) or display columns (as shown in FIG. 2a), which may be also determined according to the shape of the display screen, and this is not limited in the present disclosure.

In an exemplary embodiment, the display panel may further include a first scanning signal line, a second scanning signal line, a data signal line, a first power supply line and a second power supply line, wherein the pixel driving circuit includes a first transistor, a second transistor, a third transistor, a fourth transistor, a fifth transistor, a storage capacitor and multiple sixth transistors, and the connection of each device may be refer to FIG. 3. In this example, the multiple sixth transistors correspond to T6-Tn shown in FIG. 3, and the light-emitting signal lines control on or off of the sixth transistors based on the control of the time-sharing control signal line. Each sixth transistor is equivalent to a switch component, wherein one end of the switch component is connected to the pixel driving circuit and the other terminal of the switch component is connected to a light-emitting device, and the light-emitting device can be controlled to emit light or not by turning on or off the sixth transistor.

In this embodiment, of the multiple light-emitting devices connected to the pixel driving circuit may be controlled to emit light at the same time or in a time-sharing manner by being connected to the pixel driving circuit through a time-sharing control signal line. When emitting light at the same time, the local resolution can be reduced by displaying the same content, and when emitting light in a time-sharing manner, display resources can be saved.

An embodiment of the present disclosure further provides a method for driving a display panel, which is used to drive any of the aforementioned display panels. As shown in FIG. 4, the method may include the following steps:

Step 1, acquiring a gaze position of a viewer on the display panel;

Step 2, determining pixel islands of a gaze zone and pixel islands of a non-gaze zone in the display panel according to the gaze position;

Step 3, controlling a resolution of the pixel islands in the gaze zone to be greater than a resolution of the pixel islands in the non-gaze zone by time-sharing control signal lines.

In an exemplary embodiment, the step of controlling the resolution of the pixel islands in the gaze zone to be greater than the resolution of the pixel islands in the non-gaze zone by the time-sharing control signal lines includes:

for any one pixel island in the gaze zone, controlling light-emitting devices in multiple sub-pixels in the same pixel island to emit light in a time-sharing manner by the time-sharing control signal lines, or controlling light-emitting devices in multiple sub-pixels in different pixel islands to emit light in a time-sharing manner.

In the gaze zone, only some sub-pixels are turned on at the same time, which can save display resources.

In an exemplary embodiment, the step of controlling the resolution of the pixel islands in the gaze zone to be greater than the resolution of the pixel islands in the non-gaze zone by the time-sharing control signal lines includes:

for any one pixel island in the non-gaze zone, controlling light-emitting devices in multiple sub-pixels in the same pixel island to emit light at the same time and display the same content or not to emit light at the same time by the time-sharing control signal lines, or controlling light-emitting devices in multiple sub-pixels in different pixel islands to emit light at the same time and display the same content or not emit light at the same time.

In the non-gaze zone, the local resolution can be reduced by controlling the light-emitting devices to emit light at the same time or not to emit light at the same time.

In an exemplary embodiment, for pixel islands in the non-gaze zone, the method further includes:

dividing the display region according to pixel island columns, respectively counting the sub-pixels to be turned on in each sub-region under the current viewing angle, and transmitting light-emitting control signals to light-emitting devices in corresponding sub-pixels through time-sharing control signal lines according to the determined sub-pixels to be turned on in each sub-region.

In an exemplary embodiment, the step of counting the sub-pixels to be turned on in each sub-region under the current viewing angle includes:

for any one sub-region, removing a union set of the sub-pixels to be turned on in all pixel island columns in the sub-region, and determining the sub-pixels to be turned on in the current sub-region.

In an exemplary embodiment, the method further includes: transmitting a 0 gray scale signal to sub-pixels which are not to be turned on but are actually turned on in each sub-region.

In this embodiment, by controlling the gaze zone and the non-gaze zone differently, it is possible to light up only part of the sub-pixels.

According to the embodiment of the present disclosure, the resolution of pixel islands of the gaze zone are controlled to be greater than pixel islands of the non-gaze zone by the time-sharing control signal lines, so that the local resolution of the non-gaze zone is reduced, and the display resources of the gaze zone can be saved.

The above solution is described below through exemplary embodiments.

### Embodiment 1

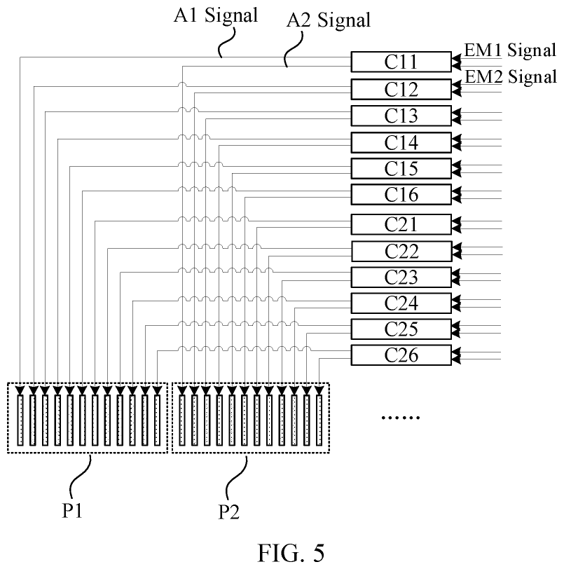

In this embodiment, the pixel arrangement shown in FIG. 2a is used, in which each pixel island contains 12 sub-pixels, each sub-pixel contains one light-emitting device, at least one sub-pixel includes a pixel driving circuit, and 12 light-emitting devices in one pixel island may be driven by two groups of pixel driving circuits. As shown in FIG. 5 (only two pixel islands are shown in the figure), for two pixel islands in any row of pixel islands in the display region, there is a group of six pixel driving circuits in each group, and each pixel driving circuit drives light-emitting devices in sub-pixels at corresponding positions in the two pixel islands to emit light simultaneously or in a time-sharing manner based on two light-emitting control signals (first light-emitting control signal EM1 and second light-emitting control signal EM2) output by the light-emitting signal driver. In this embodiment, one pixel driving circuit can control two sub-pixels in a time-sharing manner, so two groups of totally 12 pixel driving circuits are needed to drive two pixel islands.

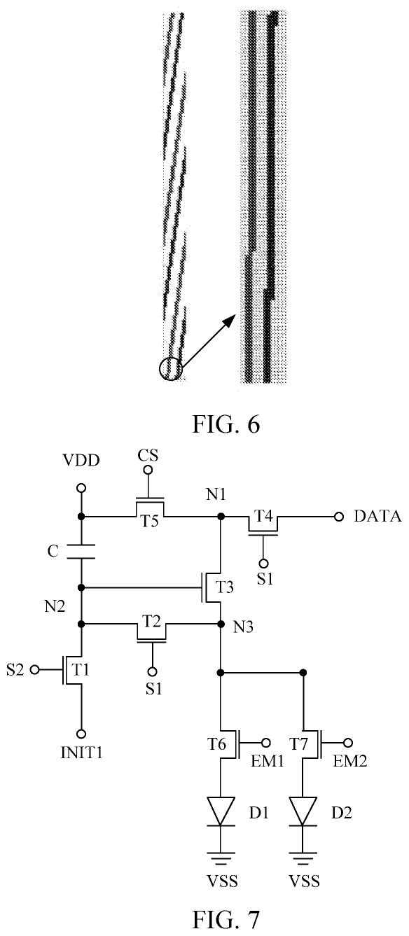

In this example, based on the control of the first light-emitting control signal EM1, the sixth transistor in the first pixel driving circuit C11 in the first group is turned on, and the first pixel driving circuit C11 outputs a first on signal A1 for emitting light to the light-emitting device included in a first sub-pixel in a first pixel island P1. Based on the control of the second light-emitting control signal EM2, the first pixel driving circuit C11 outputs a second on signal A2 for emitting light to the light-emitting device included in the first sub-pixel in the second pixel island P2, wherein the second pixel island is a pixel island adjacent to the first pixel island in the column direction. This is because when displaying 3D data with a display panel using pixel island technology, only some sub-pixels in a pixel island are turned on at the same time, for example, only 4 to 6 sub-pixels among the 12 sub-pixels may be turned on, and the sub-pixels which are not turned on have no data, that is, the gray scale is 0. The display pattern of pixel islands in the same column is the same, that is, the turned-on sub-pixels in each pixel island in a column are the same. The schematic diagram shown in FIG. 6 may be obtained by representing a column of sub-pixels with a row. In the same way, a second pixel driving circuit C12 in the first group outputs a first on signal A1 to the light-emitting device included in a second sub-pixel in the first pixel island P1 based on the first light-emitting control signal EM1, and outputs a second on signal A2 to the light-emitting device included in a second sub-pixel in the second pixel island P2 based on the second light-emitting control signal EM2. The third pixel driving circuit C13 in the first group outputs a first on signal A1 to the light-emitting device included in a third sub-pixel in the first pixel island P1 based on the first light-emitting control signal EM1, and outputs a second on signal A2 to the light-emitting device included in a third sub-pixel in the second pixel island P2 based on the second light-emitting control signal EM2. The fourth pixel driving circuit C14 in the first group outputs a first on signal A1 to the light-emitting device included in a fourth sub-pixel in the first pixel island P1 based on the first light-emitting control signal EM1, and outputs a second on signal A2 to the light-emitting device included in a fourth sub-pixel in the second pixel island P2 based on the second light-emitting control signal EM2. The fifth pixel driving circuit C15 in the first group outputs a first on signal A1 to the light-emitting device included in a fifth sub-pixel in the first pixel island P1 based on the first light-emitting control signal EM1, and outputs a second on signal A2 to the light-emitting device included in a fifth sub-pixel in the second pixel island P2 based on the second light-emitting control signal EM2. The sixth pixel driving circuit C16 in the first group outputs a first on signal A1 to the light-emitting device included in a sixth sub-pixel in the first pixel island P1 based on the first light-emitting control signal EM1, and outputs a second on signal A2 to the light-emitting device included in a sixth sub-pixel in the second pixel island P2 according to the second light-emitting control signal EM2. The light-emitting devices emit light according to the on signals, and the corresponding sub-pixels are light up.

A first pixel driving circuit C21 in the second group outputs a first on signal A1 to a seventh light-emitting device in the first pixel island P1 based on the first light-emitting control signal EM1, and outputs a second on signal A2 to a seventh light-emitting device in the second pixel island P2 based on the second light-emitting control signal EM2. A second pixel driving circuit C22 in the second group outputs a first on signal A1 to an eighth light-emitting device in the first pixel island P1 based on the first light-emitting control signal EM1 and a second on signal A2 to an eighth light-emitting device in the second pixel island P2 based on the second light-emitting control signal EM2. A third pixel driving circuit in the second group outputs a first on signal A1 to a ninth light-emitting device in the first pixel island P1 based on the first light-emitting control signal EM1 and outputs a second on signal A2 to a ninth light-emitting device in the second pixel island P2 based on the second light-emitting control signal EM2. A fourth pixel driving circuit C24 in the second group outputs a first on signal A1 to a tenth light-emitting device in the first pixel island P1 based on the first light-emitting control signal EM1, and outputs a second on signal A2 to a tenth light-emitting device in the second pixel island P2 based on the second light-emitting control signal EM2. A fifth pixel driving circuit C25 in the second group outputs a first on signal A1 to an eleventh light-emitting device in the first pixel island P1 based on the first light-emitting control signal EM1 and outputs a second on signal A2 to an eleventh light-emitting device in the second pixel island P2 based on the second light-emitting control signal EM2. A sixth pixel driving circuit C26 in the second group outputs a first on signal A1 to a twelfth light-emitting device in the first pixel island P1 based on the first light-emitting control signal EM1 and outputs a second on signal A2 to a twelfth light-emitting device in the second pixel island P2 based on the second light-emitting control signal EM2.

The EM signals received by the pixel driving are from the light-emitting signal driver shown in FIG. 1. In this example, the light-emitting signal driver outputs two light-emitting control signals to all pixel driving circuits in each display row.

This embodiment only takes the example in which the number of sub-pixels is 12, and one pixel driving circuit outputs two light-emitting control signals, a total of 12 pixel driving circuits (2 groups, 6 in each group) are needed to drive two pixel islands. The number of pixel driving circuits needed depends on the number of sub-pixels included in the pixel islands and the number of light-emitting devices that can be controlled by the pixel driving circuits.

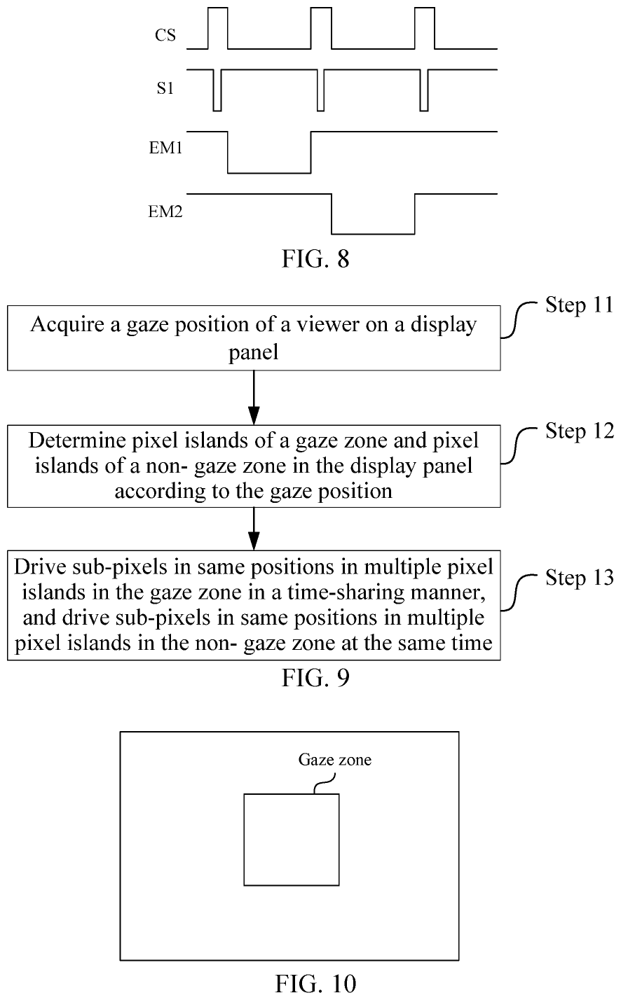

In this example, the structure of each pixel driving circuit is as shown in FIG. 7. The circuit structure in FIG. 7 is described with reference to FIG. 3, which will not be repeated here. In FIG. 7, D1 is a sub-pixel, and D2 is a sub-pixel in the same position as D1 but in different pixel islands. For example, D1 is the first sub-pixel in the first pixel island, and D2 is the first sub-pixel in the second pixel island. The turn-on and turn-off of the light-emitting control transistors T6 and T7 may be controlled by the light-emitting control signals EM1 and EM2 in a time-sharing manner, thereby controlling the light-emitting devices D1 and D2 to be turned on in a time-sharing manner. For example, the turn-on and turn-off of EM1 and EM2 may be controlled by time-sharing the potential change of the time-sharing control signal line CS, whose timing sequence is shown in FIG. 8, in which CS is used to drive the pixel driving circuit to output the light-emitting control signal EM1 or EM2, and the scanning signal line S1 is used to turn on the transistor T4, thereby inputting data in the data signal line DATA.

A connecting line between the pixel driving circuit C and the sub-pixel in FIG. 5 is the lead between the transistor T6 and the light-emitting device D1 in FIG. 7 (or the lead between T7 and the light-emitting device D2). The pixel driving circuit outputs a signal A1 and makes the light-emitting device D1 emit light when the transistor T6 is turned on based on the control of the signal EM1, and the pixel driving circuit outputs a signal A2 and makes the light-emitting device D2 emit light when the transistor T7 is turned on based on the control of the signal EM2. In FIG. 5, each pixel driving circuit C is located in a display row in the display panel, and the signals EM1 and EM2 output by the light-emitting signal driver run through all pixel driving circuits in a display row.

It can be seen that in a light-emitting stage, the pixel driving circuit can drive sub-pixels at the same positions of different pixel islands to turn on or off in a time-sharing manner based on the light-emitting control signals output by the light-emitting signal driver.

The use of pixel island technology can improve the display resolution. When the time-sharing pixel driving circuits are used to drive the pixel islands in a time-sharing manner, the number of pixel driving circuits may be reduced, the difficulty of circuit layout can be decreased accordingly, and the difficulty of manufacturing processes can be simplified.

In a display process, because users focus differently on the gaze zone and the non-gaze zone, the local resolution of the non-gaze zone may be reduced to save resources. In an exemplary embodiment, the method including the following steps may be adopted, as shown in FIG. 9:

Step 11, acquiring a gaze position of a viewer on the display panel;

FIG. 10 is a schematic diagram of a gaze zone. When human eyes watch the screen, the sight will focus on a certain zone on the screen, which is referred to as the gaze zone. The gaze zone may be a viewpoint zone or a zone containing viewpoints. There may be one gaze zone or multiple gaze zones (for example, when many people are watching, there may be multiple gaze zones). In the gaze zone, human eyes can clearly recognize contents in a picture, while in the non-gaze zone, the contents in the picture cannot be clearly seen. Therefore, resources can be saved by reducing the resolution of the non-gaze zone.

For example, the position of the gaze zone may be obtained by facial recognition, eye tracking and other technologies. In an exemplary embodiment, the viewing angle of human eyes may also be obtained.

Step 12, determining pixel islands of a gaze zone and pixel islands of a non-gaze zone in the display panel according to the gaze position; and

Step 13, controlling a resolution of the pixel islands in the gaze zone to be greater than a resolution of the pixel islands in the non-gaze zone by time-sharing control signal lines, which includes: driving sub-pixels in multiple pixel islands at the same positions in the gaze zone in a time-sharing manner, and driving sub-pixels in multiple pixel islands at the same positions in the non-gaze zone at the same time.

When the sub-pixels are located in the gaze zone, the sub-pixels located at the same positions in two adjacent pixel islands are driven in a time-sharing manner by using the time-sharing pixel driving circuit in this embodiment, as mentioned above, which will not be repeated here.

When the sub-pixels are located in the non-gaze zone, the pixel driving circuit of the sub-pixels can turn on all the sub-pixels controlled by the driving circuit, so that all the sub-pixels controlled by the pixel driving circuit display the same content, thereby locally reducing the local resolution. For example, the time-sharing pixel driving circuit shown in FIG. 7 is used to simultaneously drive the sub-pixels located at the same positions in two adjacent pixel islands, that is, the light-emitting control transistors (T6 and T7 shown in FIG. 7) of the two sub-pixels are turned on at the same time, so that the light-emitting devices D1 and D2 display the same content.

This embodiment only illustrates one pixel driving circuit driving two light-emitting devices (sub-pixels) at the same time as an example. In other embodiments, the number of sub-pixels included in the pixel islands and the number of light-emitting devices simultaneously driven by the pixel driving circuits may be adjusted, which is not limited by the present disclosure.

### Another Embodiment

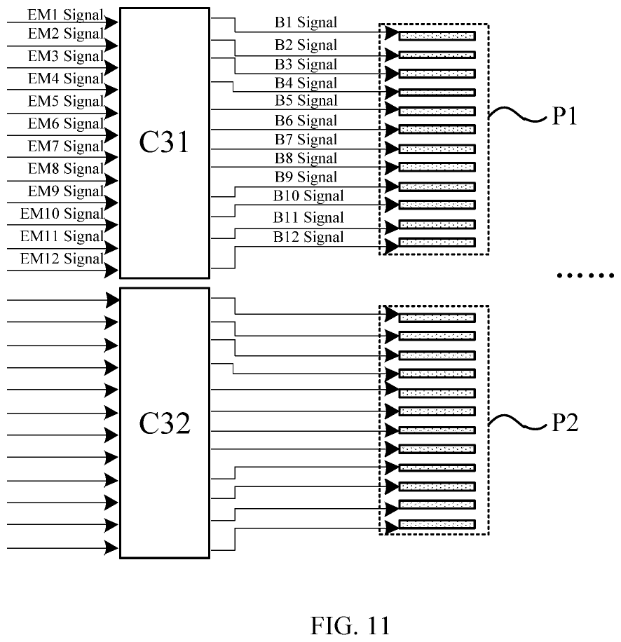

In this embodiment, the pixel arrangement shown in FIG. 2b is used, each pixel island contains 12 sub-pixels, each sub-pixel contains one light-emitting device, at least one sub-pixel includes a pixel driving circuit, and all sub-pixels in a pixel island are driven by a pixel driving circuit. As shown in FIG. 11 (showing only two pixel islands), for one pixel island in any column of pixel islands in the display region, corresponding pixel driving circuit controls twelve light-emitting devices to emit light simultaneously or in a time-sharing manner based on twelve light-emitting control signals (first light-emitting control signal EM1—twelfth light-emitting control signal EM12) output by the light-emitting signal driver.

As shown in FIG. 11, in this example, the first pixel driving circuit C31 outputs a first on signal B1 to the light-emitting device included in a first sub-pixel in a first pixel island P1 based on the first light-emitting control signal EM1, outputs a second on signal B2 to the light-emitting device included in a second sub-pixel in the first pixel island P1 based on the second light-emitting control signal EM2, outputs a third on signal B3 to the light-emitting device included in a third sub-pixel in the first pixel island P1 based on the third light-emitting control signal EM3, outputs a fourth on signal B4 to the light-emitting device included in a fourth sub-pixel in the first pixel island P1 based on the fourth light-emitting control signal EM4, outputs a fifth on signal B5 to the light-emitting device included in a fifth sub-pixel in the first pixel island P1 based on the fifth light-emitting control signal EM5, outputs a sixth on signal B6 to the light-emitting device included in a sixth sub-pixel in the first pixel island P1 based on the sixth light-emitting control signal EM6, outputs a seventh on signal B7 to the light-emitting device included in a seventh sub-pixel in the first pixel island P1 based on the seventh light-emitting control signal EM7, outputs an eighth on signal B8 to the light-emitting device included in an eighth sub-pixel in the first pixel island P1 based on the eighth light-emitting control signal EM8, outputs a ninth on signal B9 to the light-emitting device included in a ninth sub-pixel in the first pixel island P1 based on the ninth light-emitting control signal EM9, outputs a tenth on signal B10 to the light-emitting device included in a tenth sub-pixel in the first pixel island P1 based on the tenth light-emitting control signal EM10, outputs an eleventh on signal B11 to the light-emitting device included in an eleventh sub-pixel in the first pixel island P1 based on the eleventh light-emitting control signal EM11, and outputs a twelfth on signal B12 to the light-emitting device included in a twelfth sub-pixel in the first pixel island P1 based on the twelfth light-emitting control signal EM12.

The EM signals received by the pixel driving circuits are from the light-emitting signal driver as shown in FIG. 1. In this example, the light-emitting signal driver outputs twelve light-emitting control signals to all pixel driving circuits in each display row.

This embodiment only takes the example in which the number of sub-pixels is 12, and one pixel driving circuit can output 12 light-emitting control signals, therefore only one pixel driving circuit is needed to drive one pixel island.

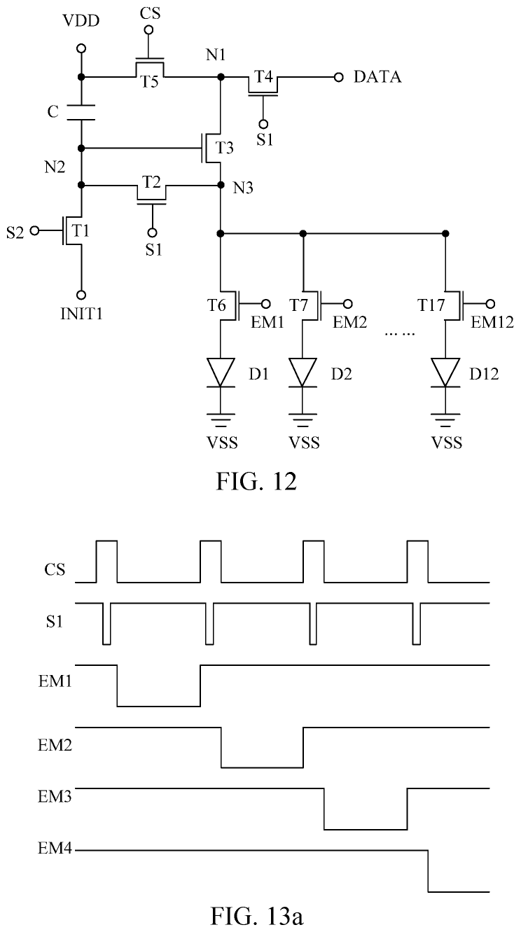

In this example, the structure of each pixel driving circuit is as shown in FIG. 12. The circuit structure in FIG. 12 is described with reference to FIG. 3, and will not be repeated here. D1 shown in FIG. 12 is a sub-pixel, and D1 to D12 are sub-pixels belonging to one pixel island. Twelve light-emitting control signals (EM) can control the turn-on and turn-off of the light-emitting control transistors T6 to T17 in a time-sharing manner, thereby controlling whether the light-emitting devices D1 to D12 are turned on or not.

In FIG. 12, when the transistor T6 is turned on based on the control of signal EM1, the pixel driving circuit outputs signal B1 to make the light-emitting device D1 emit light. When the transistor T7 is turned on based on the control of signal EM2, the pixel driving circuit outputs signal B2 to make the light-emitting device D2 emit light, . . . , and when the transistor T17 is turned on based on the control of signal EM12, the pixel driving circuit outputs signal B12 to make the light-emitting device D12 emit light. In FIG. 11, each pixel driving circuit C is located in a display row in the display panel, and the signals EM1 to EM12 output by the light-emitting signal driver run through all pixel driving circuits in a display row.

For any one pixel island, and for any one or more sub-pixels in the pixel island, if the one or more sub-pixels are not to be displayed, that is, the corresponding light-emitting devices are not to be turned on. They are then controlled by corresponding EM signals. For example, if the input signal EM is at a high level, the corresponding one or more light-emitting control transistors are turned off, and the light-emitting devices connected to the light-emitting control transistors will not emit light. EMs corresponding to multiple sub-pixels which do not need to display data may input the same EM signals, thereby achieving gray scale combination. In addition, the sub-pixels are controlled by EM, so there is no need to write 0 gray-scale signals through data signal lines, which can reduce scanning times and data transmission resources.

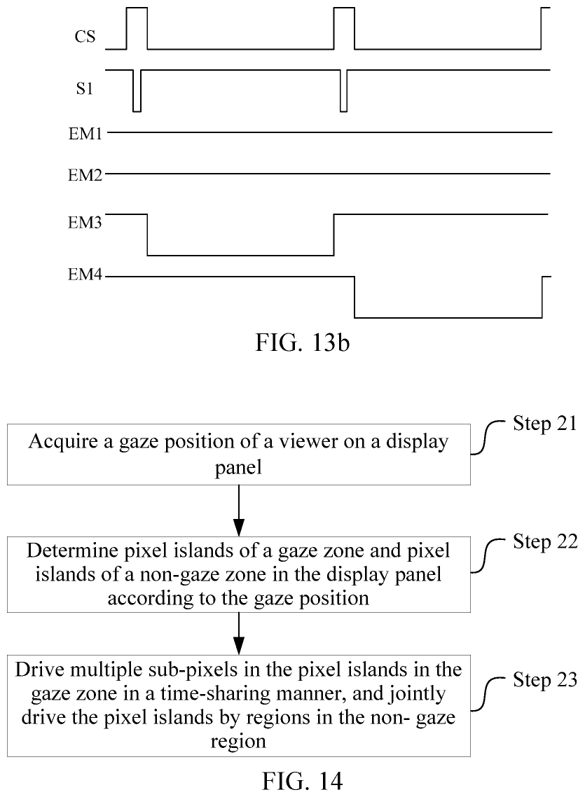

FIG. 13a is a timing diagram of four light-emitting devices which are turned on respectively. FIG. 13b is a timing diagram where two of the four light-emitting devices are turned on and the other two light-emitting devices are not turned on. For the light-emitting devices that are not lit, their EM signals are the same. In the figure, taking a time-sharing by 4 as an example, after the time-sharing, the scanning times of the time-sharing control signal line CS and the scanning signal line S1 are changed from 4 times in FIGS. 13a to 2 times in FIG. 13b, and the low-level duty cycle of light-emitting control signals EM3 and EM4 is changed from 25% to 50%.

In the display process, because users focus differently on the gaze zone and the non-gaze zone, the local resolution of the non-gaze zone may be reduced to save resources. In an exemplary embodiment, the method including the following steps may be adopted, as shown in FIG. 14:

Step 21, acquiring a gaze position of a viewer on the display panel;

Step 22, determining pixel islands of a gaze zone and pixel islands of a non-gaze zone in the display panel according to the gaze position; and

Act 23, controlling a resolution of the pixel islands in the gaze zone to be greater than the resolution of the pixel islands in the non-gaze zone through the time-sharing control signal line, which includes: driving multiple sub-pixels in the pixel islands in the gaze zone in a time-sharing manner, and jointly driving the pixel islands in different sub-regions in the non-gaze zone.

When the sub-pixels are located in the gaze zone, multiple sub-pixels in adjacent pixel islands are driven in a time-sharing manner by using the time-sharing pixel driving circuit in this embodiment, as mentioned above, which will not be repeated here.

When the sub-pixels are located in the gaze zone, it is considered that the viewing angle of human eyes will determine which sub-pixels need to be light up during 3D display. Therefore, simulation may be performed in advance to count and record the number of sub-pixels to be light up under different viewing angles, so that the corresponding sub-pixels are turned on according to the pre-record during display. In order to reduce the processing complexity, pixel islands may be jointly driven on the basis of the pre-record. For example, the joint driving of the pixel islands may be performed as follows:

Step 231, acquiring all sub-pixels (sub-pixel serial numbers) to be light up under the current viewing angle;

Step 232, dividing the display region according to pixel island columns, for example, multiple columns of pixel islands are divided as one region;

Step 233, for each sub-region, dividing the region into multiple sub-regions according to the sub-pixels to be light up, and the sub-pixels to be light up in one sub-region are the same; and

Step 234, determining the sub-pixels to be light up in the region according to the sub-pixels to be light up in each sub-region, for example, the sub-pixels to be light up in each sub-region in the region may be combined to obtain the sub-pixels to be light up in the region.

In other embodiments, the sub-regions may not be divided, that is, Step 234 may be omitted, and all sub-pixels in the region that need to be light up may be directly counted.

Step 235, transmitting a light-emitting control signal to corresponding sub-pixels according to the determined sub-pixels to be light up in the region.

For example, as shown in Table 1, a display region containing 100 columns of pixel islands is taken as an example. In this example, 50 columns of pixel islands are divided into one region, and the total is divided into two regions. In region 1, columns 1-22 have the same number of the sub-pixels to be light up, so they can be divided into one sub-region. Subsequently, there are 5 sub-regions in region 1 and 3 sub-regions in region 2. Taking region 1 as an example, the first sub-region in region 1 is the pixel islands in columns 1-22, and the sub-pixels to be light up are the second, third, seventh and eighth; the second sub-region in region 1 is the pixel islands in columns 23-25, and the sub-pixels to be light up are the second, third, seventh, eighth and ninth; the third sub-region in region 1 is the pixel islands in columns 26-34, and the sub-pixels to be light up are the second, third, eighth and ninth; the fourth sub-region in region 1 is the pixel islands in columns 35, and the sub-pixels to be light up are the third, eighth and ninth; and the fifth sub-region in region 1 is the pixel islands in columns 36-50, and the sub-pixels to be light up are the third, fourth, eighth and ninth. Taking a union set of the sub-pixels to be light up in all the sub-regions in region 1, it may be determined that the sub-pixels to be light up in region 1 are 2, 3, 4, 7, 8 and 9. In the same way, it may be determined that the sub-pixels to be light up in region 2 are 3, 4, 8, 9 and 10. After determining the sub-pixels to be light up in region 1 and region 2, for all pixel island columns in region 1, i.e., pixel islands in columns 1-50, the light-emitting control transistors corresponding to sub-pixels 2, 3, 4, 7, 8 and 9 are turned on, so that the sub-pixels are light up. For sub-pixels which do not need to be light up, the 0 gray scale signals may be written through the data signal lines. For example, for the 4th and 9th sub-pixels in the 1st-22nd columns of pixel islands, the 4th sub-pixel in the 23rd-25th columns of pixel islands, the 4th and 7th sub-pixels in the 26th-34th columns of pixel islands, the 2nd, 4th and 7th sub-pixels in the 35th column of pixel islands, and the 2nd and 7th sub-pixels in the 36th-50th columns of pixel islands in region 1, 0 gray-scale signals may be written through data signal lines.

TABLE 1

| | | Sub-pixels | Sub-pixels |
|---|---|---|---|
| | Pixel island | to be light | to be light |
| Region | column | up before | up after |
| serial number | serial number | combination | combination |
| Region 1 | 1-22 | 2, 3, 7, 8 | 2, 3, 4, 7, 8, 9 |
| | 23-25 | 2, 3, 7, 8, 9 | |
| | 26-34 | 2, 3, 8, 9 | |
| | 35 | 3, 8, 9 | |
| | 36-50 | 3, 4, 8, 9 | |
| Region 2 | 50-95 | 3, 4, 8, 9 | 3, 4, 8, 9, 10 |
| | 96-98 | 3, 4, 8, 9, 10 | |
| | 99-100 | 3, 4, 9, 10 | |

An embodiment of the present disclosure further provides a display apparatus which includes any display substrate of the aforementioned embodiments. The display apparatus may be: any product or component with a display function, such as a mobile phone, a tablet computer, a television, a display, a laptop computer, a digital photo frame, or a navigator.

Although the implementation modes of the present disclosure are disclosed above, the contents are only implementation modes used for ease of understanding of the present disclosure and not intended to limit the present disclosure. Those skilled in the art may make any modification and variation to implementation forms and details without departing from the spirit and scope disclosed by the present disclosure. However, the patent protection scope of the present disclosure should also be subject to the scope defined by the appended claims.

What is claimed is:

1. A display panel comprising a plurality of pixel islands, at least one of the plurality of pixel islands comprises a plurality of sub-pixels, at least one of the plurality of sub-pixels comprises a pixel driving circuit and a light-emitting device, at least one of the pixel driving circuits is connected to the light-emitting devices in the plurality of sub-pixels; the plurality of sub-pixels are located in one pixel island or in different pixel islands, and the at least one pixel driving circuit is connected to a time-sharing control signal line, wherein the time-sharing control signal line is configured to control a plurality of light-emitting devices to emit light at the same time or to emit light in a time-sharing manner.

2. The display panel according to claim 1, wherein at least one of the pixel driving circuits is connected to the light-emitting devices in the plurality of sub-pixels as follows:
one pixel driving circuit is connected to all sub-pixels in one pixel island; or
one pixel driving circuit is connected to a x-th sub-pixel in a first pixel island and a x-th sub-pixel in a second pixel island, wherein the first pixel island and the second pixel island are adjacent pixel islands.

3. The display panel according to claim 1, wherein
the plurality of pixel islands comprise pixel islands of a first color, pixel islands of a second color and pixel islands of a third color, and a pixel island of the first color, a pixel island of the second color and a pixel island of the third color which are adjacent form a pixel island group, wherein the pixel island groups are disposed in an array in the display panel.

4. The display panel according to claim 3, wherein
the sub-pixels in the pixel islands are rectangular, and a plurality of rectangular sub-pixels in a pixel island are disposed in a manner that long sides of the rectangles are adjacent, and extension lines of the long sides are parallel to display rows or display columns.

5. The display panel according to claim 1, further comprising a first scanning signal line, a second scanning signal line, a data signal line, a first power supply line and a second power supply line, wherein the pixel driving circuit comprises a first transistor, a second transistor, a third transistor, a fourth transistor, a fifth transistor, a storage capacitor and a plurality of sixth transistors;
a control electrode of the first transistor is connected to the second scanning signal line, a first electrode of the first transistor is connected to a first initial signal line, and a second electrode of the first transistor is connected to a second node; a control electrode of the second transistor is connected to the first scanning signal line, a first electrode of the second transistor is connected to the second node, and a second electrode of the second transistor is connected to a third node; a control electrode of the third transistor is connected to the second node, a first electrode of the third transistor is connected to a first node, and a second electrode of the third transistor is connected to the third node; a control electrode of the fourth transistor is connected to the first scanning signal line, a first electrode of the fourth transistor is connected to the data signal line, and a second electrode of the fourth transistor is connected to the first node; a control electrode of the fifth transistor is connected to the time-sharing control signal line, a first electrode of the fifth transistor is connected to the second power supply line, and a second electrode of the fifth transistor is connected to the first node; a control electrode of each sixth transistor is connected to a light-emitting signal line, a first electrode of each sixth transistor is connected to the third node, and a second electrode of each sixth transistor is connected to a first electrode of a light-emitting device; a second electrode of the light-emitting device is connected to the first power supply line, a first terminal of the storage capacitor is connected to the second power supply line, and a second terminal of the storage capacitor is connected to the second node; and the light-emitting signal line controls on or off of the sixth transistor according to control of the time-sharing control signal line.

6. A method for driving a display panel, wherein the display panel comprises a plurality of pixel islands, at least one of the plurality of pixel islands comprises a plurality of sub-pixels, at least one of the plurality of sub-pixels comprises a pixel driving circuit and a light-emitting device, at least one of the pixel driving circuits is connected to the light-emitting devices in the plurality of sub-pixels; the plurality of sub-pixels are located in one pixel island or in different pixel islands, and the at least one pixel driving circuit is connected to a time-sharing control signal line, wherein the time-sharing control signal line is configured to control a plurality of light-emitting devices to emit light at the same time or to emit light in a time-sharing manner; and the method comprises:
acquiring a gaze position of a viewer on the display panel, and determining pixel islands of a gaze zone and pixel islands of a non-gaze zone in the display panel according to the gaze position; and
controlling a resolution of the pixel islands in the gaze zone to be greater than a resolution of the pixel islands in the non-gaze zone by the time-sharing control signal line.

7. The method according to claim 6, wherein controlling the resolution of the pixel islands in the gaze zone to be greater than the resolution of the pixel islands in the non-gaze zone by the time-sharing control signal line comprises:
for any one pixel island in the gaze zone, controlling light-emitting devices in a plurality of sub-pixels in the same pixel island to emit light in a time-sharing manner by a time-sharing control signal line, or controlling light-emitting devices in a plurality of sub-pixel in different pixel islands to emit light in a time-sharing manner.

8. The method according to claim 6, wherein controlling the resolution of the pixel islands in the gaze zone to be greater than the resolution of the pixel islands in the non-gaze zone by the time-sharing control signal line comprises:
for any one pixel island in the non-gaze zone, controlling light-emitting devices in a plurality of sub-pixels in the same pixel island to emit light and display the same content or not emit light at the same time by the time-sharing control signal line, or controlling light-emitting devices in a plurality of sub-pixels in different pixel islands to emit light and display same contents or not to emit light at the same time.

9. The method according to claim 8, wherein for the pixel islands in the non-gaze zone, the method further comprises:
dividing a display region according to pixel island columns, respectively counting sub-pixels to be light up in each region under a current viewing angle, and transmitting light-emitting control signals to light-emitting devices in corresponding sub-pixels through the time-sharing control signal line according to the determined sub-pixels to be light up in each region.

10. The method according to claim 9, wherein counting the sub-pixels to be light up in each region under the current viewing angle comprises:
for any one region, removing a union set of sub-pixels to be light up in all pixel island columns in the region, and determining the sub-pixels to be light up in the current region.

11. The method according to claim 9, wherein the method further comprises transmitting a 0 gray scale signal to sub-pixels which are not to be light up but are actually light up in each region.

12. A display apparatus comprising a display panel which comprises a plurality of pixel islands, at least one of the plurality of pixel islands comprises a plurality of sub-pixels, at least one of the plurality of sub-pixels comprises a pixel driving circuit and a light-emitting device, at least one of the pixel driving circuits is connected to the light-emitting devices in the plurality of sub-pixels; the plurality of sub-pixels are located in one pixel island or in different pixel islands, and the at least one pixel driving circuit is connected to a time-sharing control signal line, wherein the time-sharing control signal line is configured to control a plurality of light-emitting devices to emit light at the same time or to emit light in a time-sharing manner.

13. The display apparatus according to claim 12, wherein at least one of the pixel driving circuits is connected to the light-emitting devices in the plurality of sub-pixels as follows:
one pixel driving circuit is connected to all sub-pixels in one pixel island; or
one pixel driving circuit is connected to a x-th sub-pixel in a first pixel island and a x-th sub-pixel in a second pixel island, wherein the first pixel island and the second pixel island are adjacent pixel islands.

14. The display apparatus according to claim 12, wherein
the plurality of pixel islands comprise pixel islands of a first color, pixel islands of a second color and pixel islands of a third color, and a pixel island of the first color, a pixel island of the second color and a pixel island of the third color which are adjacent form a pixel island group, the pixel island groups are disposed in an array in the display panel.

15. The display apparatus according to claim 14, wherein
the sub-pixels in the pixel islands are rectangular, and a plurality of rectangular sub-pixels in a pixel island are disposed in a manner that long sides of the rectangles are adjacent, and extension lines of the long sides are parallel to display rows or display columns.

16. The display apparatus according to claim 12, wherein the display panel further comprises a first scanning signal line, a second scanning signal line, a data signal line, a first power supply line and a second power supply line, wherein the pixel driving circuit comprises a first transistor, a second transistor, a third transistor, a fourth transistor, a fifth transistor, a storage capacitor and a plurality of sixth transistors;
a control electrode of the first transistor is connected to the second scanning signal line, a first electrode of the first transistor is connected to a first initial signal line, and a second electrode of the first transistor is connected to a second node; a control electrode of the second transistor is connected to the first scanning signal line, a first electrode of the second transistor is connected to the second node, and a second electrode of the second transistor is connected to a third node; a control electrode of the third transistor is connected to the second node, a first electrode of the third transistor is connected to a first node, and a second electrode of the third transistor is connected to the third node; a control electrode of the fourth transistor is connected to the first scanning signal line, a first electrode of the fourth transistor is connected to the data signal line, and a second electrode of the fourth transistor is connected to the first node; a control electrode of the fifth transistor is connected to the time-sharing control signal line, a first electrode of the fifth transistor is connected to the second power supply line, and a second electrode of the fifth transistor is connected to the first node; a control electrode of each sixth transistor is connected to a light-emitting signal line, a first electrode of each sixth transistor is connected to the third node, and a second electrode of each sixth transistor is connected to a first electrode of a light-emitting device; a second electrode of the light-emitting device is connected to the first power supply line, a first terminal of the storage capacitor is connected to the second power supply line, and a second terminal of the storage capacitor is connected to the second node; and the light-emitting signal line controls on or off of the sixth transistor according to the control of the time-sharing control signal line.
